(19) United States
(12) Patent Application Publication
(10) Pub. No.: US 2018/0330796 A1
(43) Pub. Date: Nov. 15, 2018

(54) MEMORY DEVICE AND SENSOR DEVICE

(71) Applicant: FUJI ELECTRIC CO., LTD., Kanagawa (JP)

(72) Inventor: Yoshiyuki TSUBO, Gosyogawara-city (JP)

(21) Appl. No.: 15/939,244

(22) Filed: Mar. 28, 2018

(30) Foreign Application Priority Data
May 15, 2017 (JP) 2017-096824

(51) Int. Cl. G11C 16/34; G11C 8/12

(52) U.S. Cl. CPC G11C 16/3431; G11C 8/12

(57) ABSTRACT

A relative magnitude relation of a threshold voltage of a main cell and a threshold voltage of a monitor cell is not considered in the prior art documents. Therefore, there still is room for improvement in correctly reading out data of the main cell. Provided is a memory device with a main memory and a monitor memory having a plurality of memory cells respectively. The memory device reads out the plurality of memory cells of the main memory at a third threshold voltage if a result of reading out the plurality of memory cells of the monitor memory at a second threshold voltage does not satisfy a predetermined first criterion. Here, the third threshold voltage is lower than a first threshold voltage, the second threshold voltage is higher than the first threshold voltage, and the first threshold voltage is a read-out threshold voltage of the main memory in normal operation.

The contents of the following Japanese patent application are incorporated herein by reference:
NO. 2017-096824 filed in JP on May 15, 2017.

### BACKGROUND

### 1. Technical Field

The present invention relates to memory devices and sensor devices.

### 2. Related Art

It is known to read out data of monitor cells (also referred to as dummy cells) to read out data of main cells in accordance with changes in threshold voltages of the monitor cells (for example, refer to the Patent Documents 1 and 2). Also, it is known to read out data of main cells without using monitor cells (for example, refer to the Patent Document 3).

### PRIOR ART DOCUMENTS

### Patent Documents

Patent Document 1: Japanese Patent Application Publication No. 2009-140564.

Patent Document 2: Japanese Patent Application Publication No. 2006-114078.

Patent Document 3: Japanese Patent Application Publication No. 2006-147073.

In these Prior Art Documents, a relative magnitude relation of the threshold voltages of monitor cells with threshold voltages of main cells is not considered. Therefore, there still is room for improvement in correctly reading out data of main cells.

### SUMMARY

A first aspect of the present invention provides a memory device. The memory device may include a main memory and a monitor memory having a plurality of memory cells respectively. If a result of reading out the plurality of memory cells of the monitor memory at a second threshold voltage that is higher than a first threshold voltage does not satisfy a predetermined first criterion, the memory device may read out the plurality of memory cells of the main memory at a third threshold voltage that is lower than the first threshold voltage. The first threshold voltage may be a read-out threshold voltage of the main memory in normal operation.

The plurality of memory cells of the main memory and the monitor memory may be electrically connected to a single wordline.

A situation in which a result of reading out the plurality of memory cells of the monitor memory at the second threshold voltage does not satisfy the predetermined first criterion may be, a situation in which an error occurs in at least one of the plurality of memory cells of the monitor memory as a result of reading out the plurality of memory cells of the monitor memory at the second threshold voltage. If the first criterion is not satisfied, and if no error occurs in all of the plurality of memory cells of the monitor memory as a result of reading out the plurality of memory cells of the monitor memory at a fourth threshold voltage that is lower than the second threshold voltage, the plurality of memory cells of the main memory may be read out at the third threshold voltage.

The memory device may read out the plurality of memory cells of the main memory at the first threshold voltage before reading out the plurality of memory cells of the monitor memory at the second threshold voltage.

Based on the result of reading out the plurality of memory cells of the main memory at the third threshold voltage, the memory device may refresh the plurality of memory cells of the main memory.

Based on the result of reading out the plurality of memory cells of the monitor memory at the fourth threshold voltage that is lower than the second threshold voltage, the memory device may refresh the plurality of memory cells of the monitor memory.

If the result of reading out the plurality of memory cells of the monitor memory at the fourth threshold voltage that is lower than the second threshold voltage does not satisfy a predetermined second criterion, the memory device may set a flag indicating that data holding characteristics of the plurality of memory cells of the main memory is abnormal.

The fourth threshold voltage may be higher than or equal to the first threshold voltage.

If the result of reading out the plurality of memory cells of the monitor memory at the second threshold voltage satisfies the predetermined first criterion, the memory device may not refresh the main memory and the monitor memory.

Immediately after writing data on the plurality of memory cells of the main memory, the plurality of memory cells of the main memory may have a first threshold voltage distribution and a second threshold voltage distribution which indicate different data values from each other. The first threshold voltage that is higher than the third threshold voltage may be higher than or equal to a middle threshold voltage between an average value of the first threshold voltage distribution and an average value of the second threshold voltage distribution, and may be less than or equal to the smallest threshold voltage in the first threshold voltage distribution.

The memory device may have a first, second, and third wordlines, and a plurality of data lines. The first, second, and third wordlines may be adjacently provided. Each of the plurality of data lines may intersect the first, second, and third wordlines. The monitor memory may include the plurality of memory cells, a plurality of first additional memory cells, and a plurality of second additional memory cells. Each of the plurality of memory cells may be electrically connected to the first wordline. Each of the plurality of first additional memory cells may be electrically connected to the second wordline. The second wordline may be adjacent to the first wordline. The second wordline may be different from the first wordline. Each of the plurality of second additional memory cells may be electrically connected to the third wordline. The third wordline may be adjacent to the second wordline. The third wordline may be different from the first wordline and the second wordline. The plurality of memory cells may include a repeat region in which data are written in a first pattern having different data values. The plurality of first additional memory cells may include a repeat region in which data are written in a second pattern that is different from the first pattern. The plurality of second additional memory cells may include a repeat region in which data are written in the first pattern.

A second aspect of the present invention provides a sensor device. The sensor device may include a pressure sensing unit, a trimming circuit, and a memory device. The trimming circuit may adjust current applied to the pressure sensing unit. The memory device may store trimming data to be supplied to the trimming circuit.

The summary clause does not necessarily describe all necessary features of the embodiments of the present invention. The present invention may also be a sub-combination of the features described above.

### BRIEF DESCRIPTION OF THE DRAWINGS

FIG. 1 is a diagram showing circuit structure of a memory device 100 according to a first embodiment.

FIG. 2 is a diagram showing a main memory 20 and a monitor memory 30.

FIG. 3 is a diagram illustrating a first threshold voltage (SA0), a second threshold voltage (SA1), a third threshold voltage (SA2), and a fourth threshold voltage (SA3).

FIG. 4 is a flow diagram illustrating a data refreshing operation of the memory device 100.

FIG. 5 is a diagram illustrating the first threshold voltage (SA0).

FIG. 6 is a diagram illustrating data patterns of the monitor memory 30 in a first modification example.

FIG. 7 is a diagram showing circuit structure of a sensor device 200 according to a second embodiment.

FIG. 8 is a diagram illustrating an overview of a trimming circuit 110.

### DESCRIPTION OF EXEMPLARY EMBODIMENTS

Hereinafter, embodiments of the present invention will be described. The embodiments do not limit the invention according to the claims, and not all the combinations of the features described in the embodiments are necessarily essential to means provided by aspects of the invention.

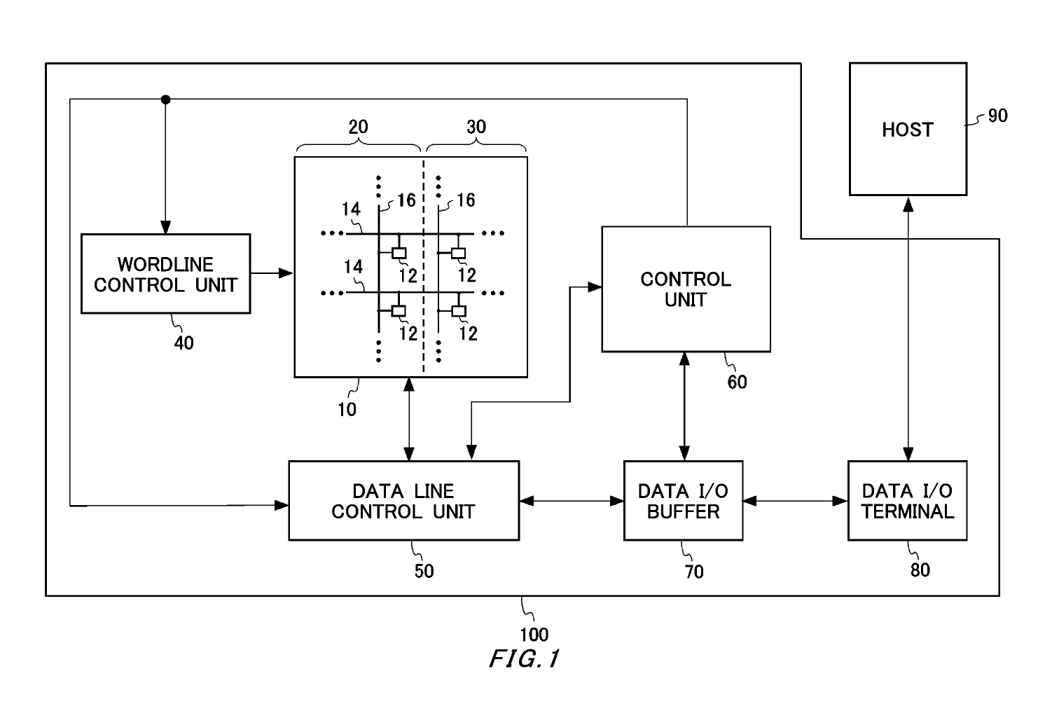

FIG. 1 is a diagram showing circuit structure of a memory device 100 according to a first embodiment. The memory device 100 of the present example includes a memory cell array 10, a wordline control unit 40, a data line control unit 50, a control unit 60, a data I/O buffer 70, and a data I/O terminal 80.

The memory cell array 10 of the present example includes a plurality of memory cells 12, a plurality of wordlines 14, and a plurality of data lines 16. In the present example, the plurality of wordlines 14 extends in the row direction and the plurality of data lines 16 extends in the column direction. One memory cell 12 may be provided near an intersection of one wordline 14 and one data line 16.

The memory device 100 of the present example is a Flash Memory device. Also, the memory cell array 10 of the present example is a NAND type array. However, in another example, the memory cell array 10 may be a NOR type array. Also, the memory cell array 10 may be an EPROM or an EEPROM.

The memory cell array 10 of the present example may include a ground (GND) selecting transistor having a source which is grounded, and a bit line selecting transistor having a drain which is electrically connected to the data lines 16. For example, 8, 16, or 32 memory cells 12 are provided between the ground selecting transistor and the bit line selecting transistor in a direction parallel to the data lines 16 (in the column direction).

The memory cell array 10 includes a main memory 20 and a monitor memory 30. The main memory 20 and the monitor memory 30 may have NAND type structure. The main memory 20 and the monitor memory 30 of the present example have a plurality of memory cells 12 respectively. Information may be recorded in the memory cells 12. The information may be data values corresponding to presence of electrons in floating gates of the memory cells 12. This information includes, for example, information of a data value “0” which corresponds to a state in which electrons are injected into the floating gates, and information of a data value “1” which corresponds to a state in which electrons are released from the floating gates.

The memory cells 12 may have flash memory structure. Specifically, the memory cells 12 may include sources and drains which are provided in semiconductor substrates, channel regions between the sources and the drains, tunnel oxide films provided on the semiconductor substrates, floating gates on the tunnel oxide films, insulating films on the floating gates, and control gates on the insulating films.

By using the wordlines 14 and the data lines 16, the memory device 100 can write data on the memory cells 12 and can read out data from the memory cells 12. For example, if data values “0” are written on the memory cells 12, electrons are injected from the semiconductor substrates to the floating gates through the tunnel oxide films. In contrast, if data values “1” are written from the memory cells 12, electrons are released from the floating gates to the semiconductor substrates through the tunnel oxide films. Releasing electrons from the floating gates to the semiconductor substrates may be expressed as erasing data.

If reading out data from the memory cells 12, a predetermined threshold voltage Vₜₕ may be applied to the control gates via the wordlines 14. If the predetermined threshold voltage Vₜₕ is applied to the control gates, source-drain current I_{ds} flows in the memory cells 12 to which electrons are not injected in their floating gates (i.e., the data value is “1”). In contrast, if predetermined threshold voltage Vₜₕ is applied to the control gate, the source-drain current I_{ds} does not flow in the memory cells 12 where electrons are injected in their floating gates (i.e., where data values are “0”). Presence of the current I_{ds} in each memory cell 12 can be detected via the data lines 16.

Electric fields from the control gates may be weakened by electrons accumulated in the floating gates of the memory cells 12. Hence, a threshold voltage Vₜₕ₀ that causes the I_{ds} to flow in the memory cells 12 where electrons are injected in their floating gates (i.e., where the data values are “0”) may be higher than a threshold voltage Vₜₕ₁ that causes the I_{ds} to flow in the memory cells 12 where electrons are not injected in their floating gates (i.e., where the data values are “1”). If reading out the data values “1”, the threshold voltage Vₜₕ may be higher than the threshold voltage Vₜₕ₁, and may be lower than the threshold voltage Vₜₕ₀. In contrast, the memory cells 12 with no I_{ds} flowing therethrough at the threshold voltage Vₜₕ may be regarded as having the data values “0”.

The wordline control unit 40 of the present example is electrically connected to a wordline 14. By selectively applying a voltage to a wordline 14, the wordline control unit 40 may select a wordline 14 to control. The wordline control unit 40 may control data writing on the memory cells 12, data read-out from the memory cells 12, and data erasing from the memory cells 12.

The data line control unit 50 of the present example is electrically connected to a data line 16. By selectively applying a predetermined voltage to a data line 16, the data line control unit 50 may select a data line 16 to control. The data line control unit 50 may control data writing on the memory cells 12, and data read-out from the memory cells 12.

The data line control unit 50 may have one sense amplifier for each data line 16. The sense amplifier may amplify a voltage signal of data read out from the memory cells 12, and hold this data temporarily. The data line control unit 50 may output data read out from each memory cell 12 to the data I/O terminal 80 via the data I/O buffer 70. The data I/O terminal 80 may output this data to a host 90. The host 90 is, for example, a PC (Personal Computer).

The host 90 may be positioned outside the memory device 100. The host 90 may specify an address of the memory cells 12 which will be a target for data writing, data read-out, and data erasing for the memory device 100. Also, the host 90 may input operation commands into the control unit 60 via the data I/O terminal 80 and the data I/O buffer 70.

The control unit 60 may have a CPU (Central Processing Unit), a ROM (Read Only Memory), etc. The control unit 60 may decode the operation commands from the host 90. Based on the decoded operation commands, the control unit 60 may control the wordline control unit 40 and the data line control unit 50. The operation commands decoded by the control unit 60 may cause the wordline control unit 40 and the data line control unit 50 to: write data on the memory cells 12; read out data from the memory cells 12; and erase data from the memory cells 12. The CPU of the control unit 60 controls, for example, voltage values supplied to the wordlines 14 by the wordline control unit 40, and controls voltage values supplied to the data lines 16 by the data line control unit 50. Also, the control unit 60 may determine whether or not data read out from the memory cells 12 satisfy a first and a second criterion described below.

The memory device 100 may have an ECC (Error Correction Code) correction unit. The ECC correction unit may detect and correct errors generated while recording or transmitting data read out from the memory cells 12.

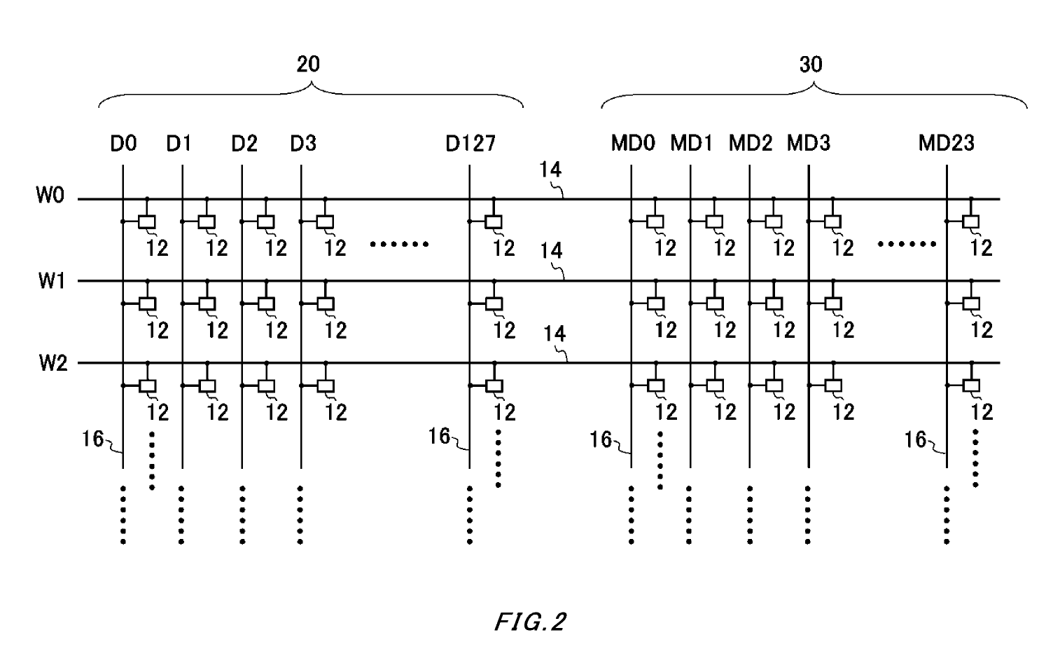

FIG. 2 is a diagram showing the main memory 20 and the monitor memory 30. Shown in FIG. 2 is three wordlines 14 (W0, W1, and W2) provided adjacently. Needless to say, the memory cell array 10 may have greater than or equal to four wordlines 14. W0, W1, and W2 are examples of a first, a second, and a third wordlines 14 respectively. In the present example, W1 is a wordline 14 adjacent to W0 and different from W0. Also, W2 is a wordline 14 adjacent to W1 and is different from W0 and W1.

Each of the plurality of data lines 16 of the present example intersects W0, W1, and W2. The main memory 20 of the present example has 128 data lines 16 (D0, D1 . . . D127), and the monitor memory 30 has 24 data lines 16 (MD0, MD1 . . . MD23). The main memory 20 and the monitor memory 30 may be distinguished from each other by the data lines 16 to which they are connected.

The memory cells 12 of the main memory 20 and the memory cells 12 of the monitor memory 30 may be electrically connected to a single wordline 14. In the present example, 128 memory cells 12 in the main memory 20 and 24 memory cells 12 of the monitor memory 30 are electrically connected to W0 respectively. In the present example, electrically connecting the memory cells 12 to the wordlines 14 means that the control gates of the memory cells 12 are electrically connected to the wordlines 14.

Similarly, the 128 memory cells 12 in the main memory 20 and the 24 memory cells 12 of the monitor memory 30 are electrically connected to W1 respectively. The memory cells 12 of the monitor memory 30 which are electrically connected to W1 are examples of a plurality of first additional memory cells. Also, the 128 memory cells 12 in the main memory 20 and the 24 memory cells 12 of the monitor memory 30 are electrically connected to W2 respectively. The memory cells 12 of the monitor memory 30 which are electrically connected to W2 are examples of the plurality of second additional memory cells.

In the present example, the wordlines 14 are shared between the main memory 20 and the monitor memory 30. Hence, the same voltage is applied to the main memory 20 and the monitor memory 30 from the wordline control unit 40. Thus, the main memory 20 and the monitor memory 30 may experience the same driving state (in other words, may experience approximately the same writing frequency). Tendency of deterioration of the memory cells 12 may become more similar between the main memory 20 and the monitor memory 30 if they are connected to a single wordline 14, compared with a situation in which they are connected to different wordlines. In the present example, by reading out the memory cell 12 in the main memory 20 and in the monitor memory 30 which are connected to a single wordline 14, changes in the threshold voltage (i.e., degree of deterioration in data) of the main memory 20 and the monitor memory 30 can be judged more accurately.

In another example, at least one memory cell 12 in the monitor memory 30 may be provided to a block or a page, which are a unit of data writing or data erasing from the main memory 20. At least one of the memory cells 12 in the monitor memory 30 may be electrically connected to any of the wordlines 14 in the main memory 20.

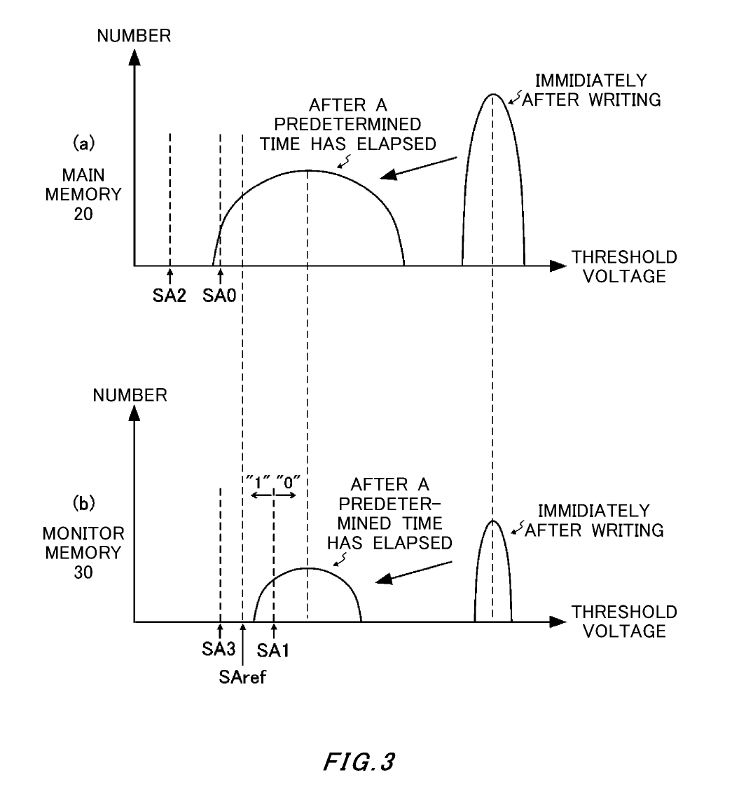

FIG. 3 is a diagram illustrating the first threshold voltage (SA0), the second threshold voltage (SA1), the third threshold voltage (SA2), and the fourth threshold voltage (SA3). In the present example, from the first threshold voltage (SA0) to the fourth threshold voltage (SA3) are used to refresh data held in the memory cell array 10.

(a) in FIG. 3 shows a threshold voltage distribution of the memory cells 12 in the main memory 20. In (a) in FIG. 3, the horizontal axis shows the threshold voltage and the vertical axis shows number. The number shows numbers of the memory cells 12 having the same threshold voltage. In contrast, (b) in FIG. 3 shows a threshold voltage distribution of the memory cells 12 in the monitor memory 30. In (b) in FIG. 3, the horizontal axis and the vertical axis show the same things as those in (a) in FIG. 3.

A threshold voltage distribution immediately after writing data on the memory cells 12 is different from a threshold voltage distribution after a predetermined time has elapsed since data are written on the memory cells 12. The threshold voltage distribution immediately after the writing is, for example, a relatively sharp distribution. In contrast, the threshold voltage distribution after a predetermined time has elapsed is, for example, a relatively flat distribution with a low average value number, compared with the threshold voltage distribution immediately after the writing.

Comparison between (a) and (b) in FIG. 3 immediately after the writing, an average value of the number (μ) is higher and the standard deviation (σ) is larger in (a) in FIG. 3. It may be considered that, this is due to the number of the memory cells 12 in the main memory 20 being sufficiently greater than the number of the memory cells 12 in the monitor memory 30 in the present example.

As time elapses after writing data on the memory cells 12, electrons exit from the floating gates of the memory cells 12 to the semiconductor substrates through the tunnel oxide films. This exit of the electrons may occur randomly and inevitably in a plurality of memory cells 12. The longer the lapsed time, the more electrons exit. Hence, it is necessary to refresh data regularly in the memory cells 12. In the present example, data refreshing operation refer to re-writing data recorded in the memory cell array 10 into the memory cells 12.

Due to the exit of the electrons from the floating gates, the threshold voltage distributions of the memory cells 12 may change. Specifically, the threshold voltage distributions of the memory cells 12 move toward a neutral threshold voltage. For example, the threshold voltage distributions move toward the neutral threshold voltage by approximately 0.5 [V] to 1 [V]. As shown at (a) and (b) in FIG. 3, after a predetermined time has elapsed, an average value number becomes small and standard deviation becomes large in the threshold voltage distributions compared with those immediately after the writing.

Degree of movement of the threshold distributions may be the same in the main memory 20 and the monitor memory 30. The main memory 20 and the monitor memory 30 of the present example exhibit matching average values of the threshold distributions immediately after the writing, and matching average values of the threshold distributions after a predetermined time has elapsed. The degree of a movement of the threshold distributions after a predetermined time has elapsed may also be attributable to a number of times of data writing and erasing, deterioration of the tunnel oxide films, etc.

The first threshold voltage (SA0) is a read-out threshold voltage of the memory cells 12 of the main memory 20 in normal operation. The read-out threshold voltage of the memory cells 12 of the main memory 20 in normal operation may be a read-out threshold voltage of the memory cells 12 in a situation in which it is assumed that the threshold voltage distributions have not changed since immediately after writing data. The first threshold voltage (SA0) has, for example, a smaller voltage value than that of the threshold voltage distributions of all of the memory cells 12 of the main memory 20 immediately after data writing, and a larger voltage value than that of the threshold voltage distributions of any memory cells 12 of the main memory 20 after a predetermined time has elapsed.

The second threshold voltage (SA1) is a threshold voltage for reading out the plurality of memory cells 12 in the monitor memory 30. The second threshold voltage (SA1) is a threshold voltage higher than the first threshold voltage (SA0). In other words, the second threshold voltage (SA1) is also a condition for reading out the memory cells 12 in a situation in which data holding time is short compared with that of the first threshold voltage (SA0).

The third threshold voltage (SA2) is a threshold voltage for reading out the plurality of memory cells 12 in the main memory 20. The third threshold voltage (SA2) is a threshold voltage lower than the first threshold voltage (SA0). In other words, the third threshold voltage (SA2) is also a condition for reading out the memory cells 12 in a situation in which data holding time is long compared with that of the first threshold voltage (SA0).

In the present example, if the result of reading out the plurality of memory cells 12 of the monitor memory 30 at the second threshold voltage (SA1) does not satisfy the predetermined first criterion, the plurality of memory cells 12 of the main memory 20 are read out at the third threshold voltage (SA2). In the present example, satisfying the first criterion means that no change occurs in data values in all of the memory cells 12 of the monitor memory 30 as a result of reading out the plurality of memory cells 12 of the monitor memory 30 at the second threshold voltage (SA1). Hence, a situation in which the first criterion is not satisfied occurs in a situation in which an error occurs (i.e., a change in the data value occurs) in at least one of the plurality of memory cells 12 of the monitor memory 30, as a result of reading out the plurality of memory cells 12 of the monitor memory 30 at the second threshold voltage (SA1). By defining that the first criterion is not satisfied if an error occurs in at least one of the memory cells 12, it is possible to enhance error detecting sensitivity compared with a situation in which it is defined that a criterion is not satisfied if an error occurs in the plurality of memory cells 12.

As shown at (b) in FIG. 3, the memory cells 12 that has higher threshold voltage than the second threshold voltage (SA1) have data values of “0”, and the memory cells 12 that have lower threshold voltage than the second threshold voltage (SA1) have data values of “1”. Thus, in the monitor memory 30 of the present example, an error occurs as a result of reading out the memory cell 12 at the second threshold voltage (SA1).

As described above, the threshold voltage distributions are different between the main memory 20 and the monitor memory 30. In the present example, the threshold voltage distributions of the main memory 20 and the monitor memory 30 are taken into account, and the monitor memory 30 is read out at the second threshold voltage (SA1) which is higher than the first threshold voltage (SA0). Thus, in the present example, data can be read out appropriately in accordance with changes in the threshold voltage distributions of both the main memory 20 and the monitor memory 30.

Even in a situation in which it is found out that as a result of reading out the monitor memory 30 at the second threshold voltage (SA1), reading out the monitor memory 30 at the reference threshold voltage (SAref) is appropriate, it is not appropriate to read out the main memory 20 at reference threshold voltage (SAref) which is lower than the second threshold voltage (SA1). Thus, it is not desirable to make values of the threshold voltage of the main memory 20 and the monitor memory 30 always the same.

The fourth threshold voltage (SA3) is a threshold voltage for reading out the plurality of memory cells 12 in the monitor memory 30. The fourth threshold voltage (SA3) is a threshold voltage lower than the second threshold voltage (SA1). The fourth threshold voltage (SA3) is also a condition for reading out the memory cells 12 in a situation in which the data holding time is long compared with that of the second threshold voltage (SA1), and the data holding time is short compared with that of the third threshold voltage (SA2).

The fourth threshold voltage (SA3) may be higher than or equal to the first threshold voltage (SA0). That is, the fourth threshold voltage (SA3) may be a condition for reading out the memory cells 12 in a situation in which the data holding time is short compared with that of the first threshold voltage (SA0). In this case, because it is possible to read out the monitor memory 30 under stricter condition than that of the main memory 20, it is possible to improve the error detecting sensitivity of the monitor memory 30 more compared with when SA3=SA0. The fourth threshold voltage (SA3) of the present example has the same voltage value as the first threshold voltage (SA0).

In the present example, if the first criterion is not satisfied, and if the second criterion is satisfied, the plurality of memory cells 12 of the main memory 20 are read out at the third threshold voltage (SA2). In the present example, satisfying the second criterion means that no change occurs (i.e., no error occurs) in all of the data values of the plurality of memory cells 12 of the monitor memory 30 as a result of reading out the plurality of memory cells 12 of the monitor memory 30 at the fourth threshold voltage (SA3). Thus, data of the main memory 20 can be read out appropriately.

A specific example of SA0 to SA3 will be described below. For example, if a voltage 3.3V is applied to the control gate without electrons injected into the floating gate it is assumed that source-drain current I_{ds} of 5 μA flows through the memory cell 12. In this case, the SA2 may be 3.8V (=3.3V+0.5V) in order to judge whether or not a little number of electrons are remaining in each memory cell 12 of the main memory 20. Also, SA0 may be 4.3V (=3.3V+0.5V+0.5V) in order to judge whether or not a sufficient number of electrons are remaining in each memory cell 12 of the main memory 20.

SA3 and SA1 used for the monitor memory 30 may be determined, considering a variation of the threshold voltage of the main memory 20. For example, as a result of performing an predetermined time acceleration test which is carried out by leaving the memory cell array 10 in high temperature environment after writing data on the memory cells 12 of the main memory 20, it is assumed that number of the main memory 20 is within a variation range of ±0.6V from the average value (the variation range is not limited to 0.6V, and may differ depending on memory sizes, specifications, etc.). In this case, SA3 may be 4.4V (=SA2+0.6V), and SA1 may be 4.9V (=SA3+0.5V).

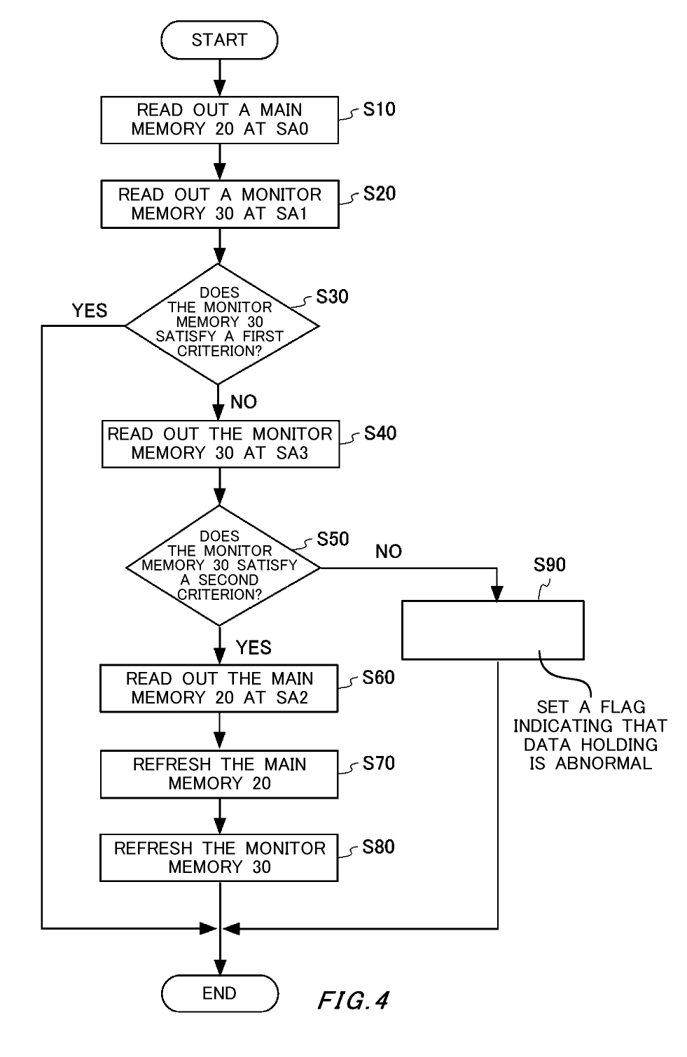

FIG. 4 is a flow diagram illustrating a data refreshing operation of the memory device 100. In the present example, starting with step S10, the data line control unit 50 reads out the plurality of memory cells 12 of the main memory 20 at the first threshold voltage (SA0).

Next, at step S20, the data line control unit 50 reads out the plurality of memory cells 12 of the monitor memory 30 at the second threshold voltage (SA1). In other words, in the present example, before reading out the plurality of memory cells 12 of the monitor memory 30 at the second threshold voltage (SA1), the plurality of memory cells 12 of the main memory 20 are read out at the first threshold voltage (SA0).

Next, at step S30, the control unit 60 determines whether or not data of the monitor memory 30 satisfy the first criterion. If the result of reading out the plurality of memory cells 12 of the monitor memory 30 at the second threshold voltage (SA1) satisfies the predetermined first criterion, i.e., if the data value does not change in all of the memory cells 12 of the monitor memory 30 (YES at step S30), the control unit 60 does not refresh the main memory 20 and the monitor memory 30. A data refreshing operation may be carried out at predetermined time intervals. If YES at step S30, data of the memory cell array 10 may not be refreshed until the next refresh timing comes.

In contrast, if the result of reading out the plurality of memory cells 12 of the monitor memory 30 at the second threshold voltage (SA1) does not satisfy the predetermined first criterion (NO at step S30), the control unit 60 reads out the plurality of memory cells 12 of the monitor memory 30 at the fourth threshold voltage (SA3) (step S40).

Next, at step S50, the control unit 60 determines whether or not data of the monitor memory 30 satisfy the second criterion. If the result of reading out the plurality of memory cells 12 of the monitor memory 30 at the fourth threshold voltage (SA3) satisfies the predetermined second criterion, i.e., if the data value does not change in all of the memory cells 12 of the monitor memory 30 (YES at step S50), the control unit 60 reads out the plurality of memory cells 12 of the main memory 20 at the third threshold voltage (SA2) (step S60). Then, based on the result of reading out at the third threshold voltage (SA2), the control unit 60 refreshes the plurality of memory cells 12 of the main memory 20 by using the wordline control unit 40 and the data line control unit 50 (step S70).

In contrast, if the result of reading out the plurality of memory cells 12 of the monitor memory 30 at the fourth threshold voltage (SA3) does not satisfy the predetermined second criterion, i.e., if the data value changes in at least one of the memory cells 12 of the monitor memory 30 (NO at step S50), the control unit 60 sets a flag indicating that a data holding characteristic of the plurality of memory cells 12 of the main memory 20 is abnormal (step S90). As there is a correlation of temporal change characteristic in threshold voltages of the main memory 20 and the monitor memory 30, based on the data holding characteristic of the monitor memory 30, it is possible to estimate that deterioration of the main memory 20 is severe. Data for the flag may be recorded in a ROM within the control unit 60.

Afte refreshing the main memory 20 at step S70, based on the result of reading out the plurality of memory cells 12 of the monitor memory 30 at the fourth threshold voltage (SA3), the control unit 60 refreshes the plurality of memory cells 12 of the monitor memory 30 by using the wordline control unit 40 and the data line control unit 50 (step S80).

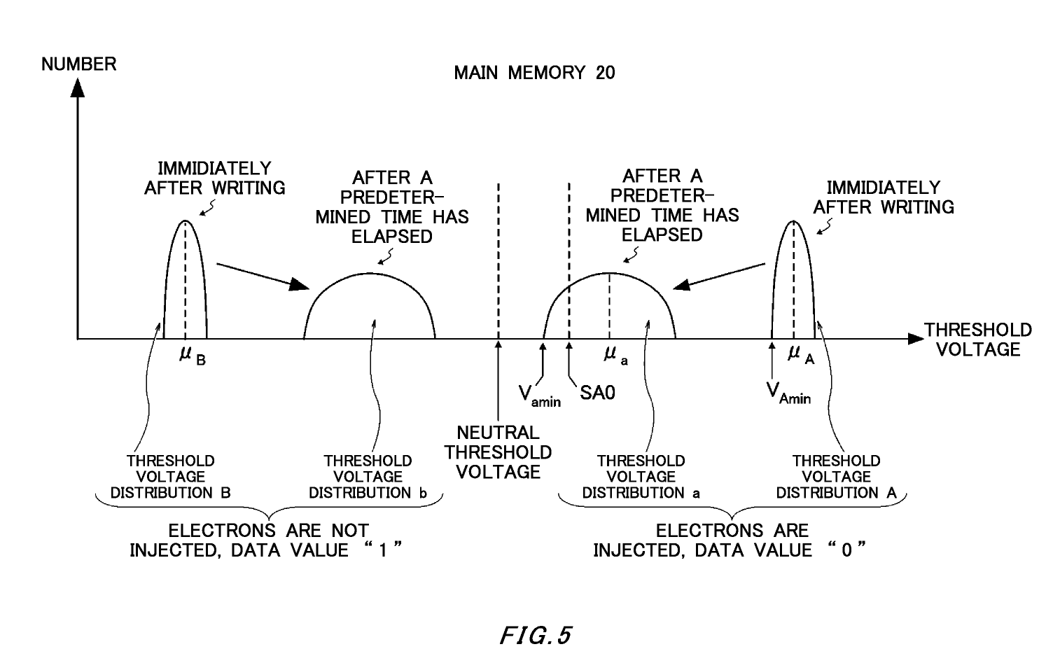

FIG. 5 is a diagram illustrating the first threshold voltage (SA0). The horizontal axis is the threshold voltage of the main memory 20, and the vertical axis is number of the main memory 20. Threshold voltage distributions A and a are threshold voltage distributions of the memory cells 12 having the data value “0”. The threshold voltage distribution A is the threshold voltage distribution of the memory cells 12 immediately after writing data on the plurality of memory cells 12 of the main memory 20. The threshold voltage distribution a is the threshold voltage distribution after a predetermined time has elapsed since data are written on the memory cells 12. The threshold voltage distribution A is an example of the first threshold voltage distribution. The threshold voltage of the threshold voltage distributions A and a are higher than the neutral threshold voltage.

The threshold voltage distributions B and b are threshold voltage distributions of the memory cells 12 having the data value “1”. The threshold voltage distribution B is the threshold voltage distribution of the memory cells 12 immediately after writing data on the plurality of memory cells 12 of the main memory 20. The threshold voltage distribution b is the threshold voltage distribution after a predetermined time has elapsed since data are written on the memory cell 12. The threshold voltage distribution B is an example of the second threshold voltage distribution. The threshold voltage of the threshold voltage distributions B and b are lower than the neutral threshold voltage.

In the present example, the first threshold voltage (SA0) may be a voltage higher than or equal to a middle threshold voltage between an average value of the threshold voltage distribution A (μ_{A}) and an average value of the threshold voltage distribution B (μ_{B}), and may be less than or equal to the smallest threshold voltage in the threshold voltage distribution A (V_{Amin}). In the present example, the middle threshold voltage between μ_{A} and μ_{B} is the neutral threshold voltage.

The first threshold voltage (SA0) of the present example is a range of the threshold voltage of the threshold voltage distribution a positioned within a range between the neutral threshold voltage and V_{Amin}. More specifically, the first threshold voltage (SA0) of the present example is within the range of, between the smallest threshold voltage of the threshold voltage distribution a (Vₐₘᵢₙ) and the average value of the threshold voltage distribution a (μₐ).

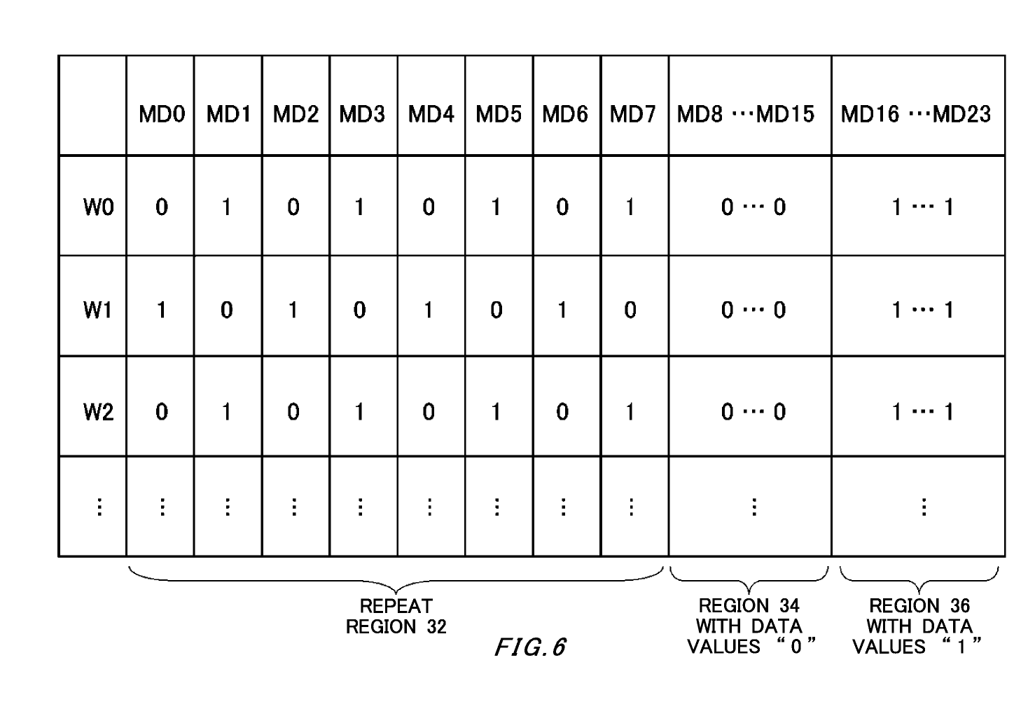

It is possible to read out the adjacent threshold voltage distribution erroneously, if at step S10 in FIG. 4, the memory cells 12 of the main memory 20 are read out at the third threshold voltage (SA2) that is smaller than the first threshold voltage (SA0). For example, at step S10, if it is tried to read out the threshold voltage distribution a at the third threshold voltage (SA2), it is possible to read out the memory cell 12 of the threshold voltage distribution b (the data value “1”) erroneously. Here, the memory cells 12 of the threshold voltage distribution b is adjacent to the memory cells 12 of the threshold voltage distribution a (the data value “0”) in FIG. 6. In the present example, it is possible to prevent such erroneous read-out, for example, by making the third threshold voltage (SA2) higher than the neutral threshold voltage.

Although the present example describes a situation in which the data values are “0” and “1”, in another example, the present example may be applied for a situation in which data values are maintained in the memory cells 12 at a multi-value level. For example, it is assumed that the first threshold voltage (SA0) is a middle threshold voltage of a plurality of threshold voltage distributions indicating “1/3”, “2/3”, and “3/3”. In the example of the multi-value level, it is possible to prevent such erroneous read-out, for example, by making the third threshold voltage (SA2) as the middle of an average value of the adjacent threshold voltage distributions.

FIG. 6 is a diagram illustrating data patterns of the monitor memory 30 in a first modification example. For example, a data value at an intersection of W0 row and MD0 column indicates a data value of a corresponding memory cell 12. The plurality of memory cells 12 of the monitor memory 30 of the present example has a repeat region 32, a region 34 with data values 0, and a region 36 with data values 1.

In the repeat region 32, the data values 0 and 1 are alternatively repeated in the extending direction of the wordlines 14. In the region 34 with data values 0, data values in all of the memory cells 12 are 0. In the region 36 with data values 1, data values of all of the memory cells 12 are 1.

In the repeat region 32, data are written in a first pattern having different data values. In the present example, the data values 0 and 1 of 8 memory cells 12 (MD0 . . . MD7) are written in the first pattern (0, 1, 0, 1, 0, 1, 0, 1) in the extending direction of the wordlines 14. Here, the 8 memory cells 12 are electrically connected to W0.

Also, the data values 0 and 1 of the 8 memory cells 12 (MD0 . . . MD7) are written in a second pattern (1, 0, 1, 0, 1, 0, 1, 0,) that is different from the first pattern, in the extending direction of the wordlines 14. Here, the 8 memory cells 12 are electrically connected to W1. The 8 memory cells 12 electrically connected to W1 are an example of the first additional memory cell.

The data values 0 and 1 of the 8 memory cells 12 (MD0 . . . MD7) are written in the first pattern (0, 1, 0, 1, 0, 1, 0, 1). Here, the 8 memory cells 12 are electrically connected to W2. The 8 memory cells 12 electrically connected to W2 are an example of the second additional memory cell.

Thus, in the repeat region 32 of the present example, the data values 0 and 1 are disposed in, so-called a checkered manner in the memory cells 12 that are disposed in a matrix form. Thus, it is possible to detect data pattern dependency at the time of data read-out and data writing.

It also depends on circuit structure in the memory cell array 10, however, generally, if the adjacent memory cells 12 have the different data values (i.e., charge states or bit values), a leakage of electrons among the memory cells 12 tends to happen more compared with a situation in which they have the same data value. For example, the leakage of electrons may happen from floating gates where electrons are injected therein to floating gates where electrons are not injected therein. Hence, the data value might be deteriorated faster in the repeat region 32.

Thus, by making a configuration in which interference among the memory cells 12 to occur easily in the monitor memory 30, it is possible to make a movement width of threshold voltage distributions in the monitor memory 30 after predetermined time has elapsed large compared with that of the main memory 20 (here, the movement width is, for example, an amount of change in an average value of threshold voltage). Hence, by judging data values of the monitor memory 30, it is possible to allow more time to decide whether or not to refresh the main memory 20, etc.

Furthermore, in the present example, the repeat region 32, the region 34 with data values 0, and the region 36 with data values 1 are provided in the monitor memory 30. A deterioration state of the data values is compared among the repeat region 32, the region 34 with data values 0, and the region 36 with data values 1 to confirm whether or not the deterioration of the data values is due to a pattern of the data values.

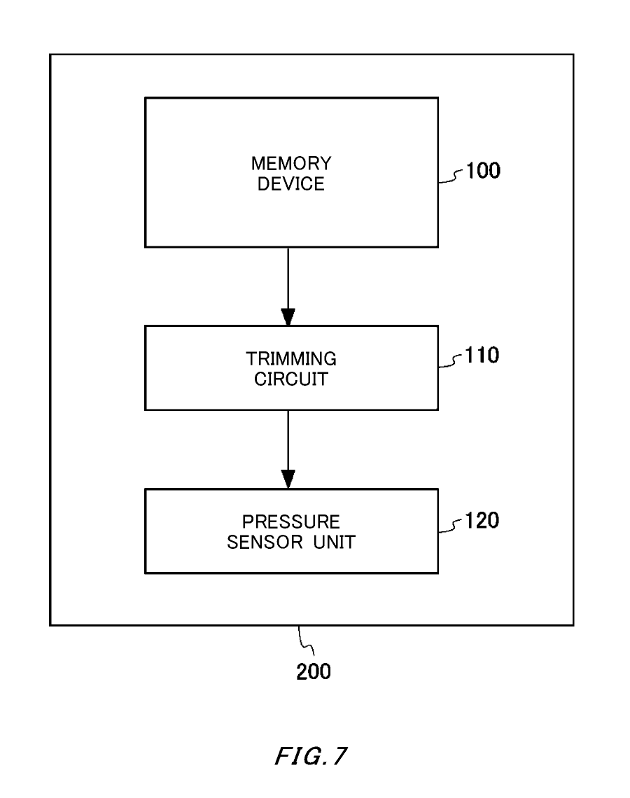

FIG. 7 is a diagram showing a circuit structure of a sensor device 200 according to a second embodiment. The sensor device 200 of the present example includes the memory device 100, the trimming circuit 110 and the pressure sensing unit 120 of the first embodiment. The memory device 100 of the present example stores trimming data to be supplied to the trimming circuit 110. The trimming circuit 110 of the present example is electrically connected to the memory device 100 and the pressure sensing unit 120. The trimming circuit 110 of the present example receives the trimming data from the memory device 100 to adjust current applied to the pressure sensing unit 120.

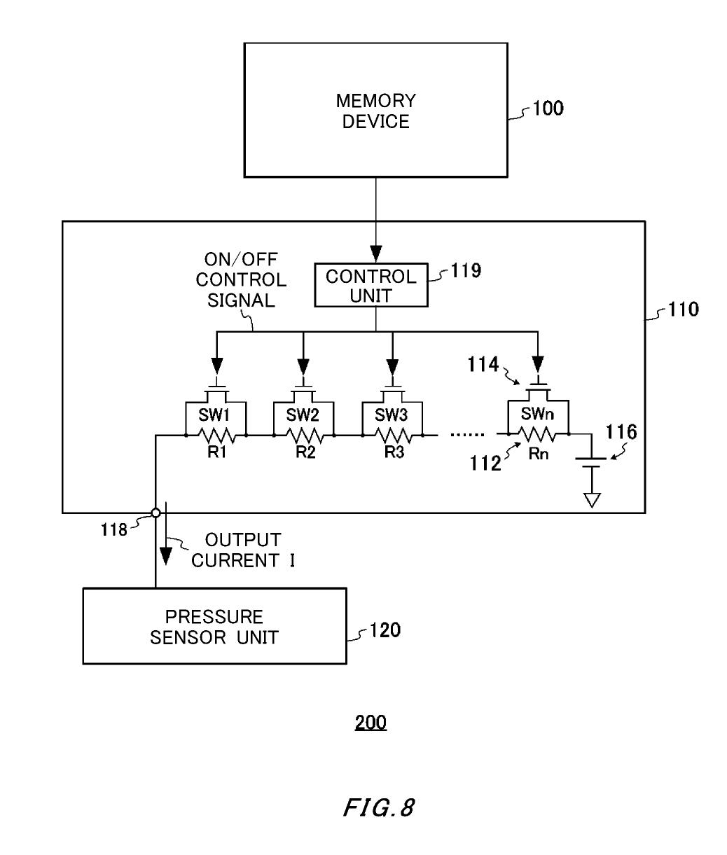

FIG. 8 is a diagram illustrating an overview of the trimming circuit 110. The trimming circuit 110 of the present example has a power supply unit 116, a plurality of resistor units 112, a plurality of switch units 114, and a control unit 119. The plurality of resistor units 112 are connected between the power supply unit 116 and an output end 118 in series toward the pressure sensing unit 120. Each switch unit 114 is provided in parallel to each resistor unit 112. Provided in the trimming circuit 110 of the present example are, n resistor units 112 and n switch units 114 (n is a natural number greater than or equal to 2).

The control unit 119 of the present example receives the trimming data from the memory device 100, and outputs a control signal for deciding which of the switch units 114 to switch on/off to the switch unit 114. The switch unit 114 may be a transistor such as a MOSFET (Metal Oxide Semiconductor Field Effect Transistor) or an IGBT (Insulated Gate Bipolar Transistor).

In the present example, on-resistance or conduction resistance in a situation in which the switch unit 114 is on-state is sufficiently small compared with resistance of the resistor unit 112. Also, resistance of the resistor unit 112 may be a value that can appropriately adjust output current I of the trimming circuit 110. The resistance value of the resistor unit 112 may be R1=R2= . . . =Rn, or may also be R1<R2< . . . <Rn. The resistance value of the resistor unit 112 may be appropriately determined according to specifications. The trimming circuit 110 can appropriately adjust the output current I in accordance with which of the switch units 114 to make on-state or how many switch units 114 to make on-state. Thus, sensitivity, temperature characteristic, offset, etc. of the pressure sensing unit 120 can be adjusted.

In an example, the sensor device 200 is use for an engine control of a motor vehicle. If the trimming data from the memory device 100 is erroneous, the sensor device 200 may not operate appropriately. Hence, it is desirable for data of the memory device 100 not to change over time. High reliability is required for the memory device 100. In the present example, it is possible to ensure reliability of data within the memory device 100, by using the memory device 100 of the first embodiment to appropriately refresh the trimming data.

Sensing data from the pressure sensing unit 120 may be sent to the host 90 illustrated in FIG. 1. Based on the sensing data, the host 90 may appropriately adjust data in the memory cell array 10 of the memory device 100.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operation, procedures, steps, and stages of each process performed by an device, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

### EXPLANATION OF REFERENCE SYMBOLS

10: Memory cell array;

12: Memory cell;

14: Wordline;

16: Data line;

20: Main memory;

30: Monitor memory;

32: Repeat region;

34: Region with the data value 0;

36: Region with the data value 1;

40: Wordline control unit;

50: Data line control unit;

60: Control unit;

70: Data I/O buffer;

80: Data I/O terminal;

90: Host;

100: Memory device;

110: Trimming circuit;

112: Resistor unit;

114: Switch unit;

116: Power supply unit;

118: Output end;

119: Control unit;

120: Pressure sensing unit;

200: Sensor device

What is claimed is:

1. A memory device comprising a main memory and a monitor memory each of which has a plurality of memory cells, wherein,
the plurality of memory cells of the main memory are read out at a third threshold voltage if a result of reading out the plurality of memory cells of the monitor memory at a second threshold voltage does not satisfy a predetermined first criterion, wherein the third threshold voltage is lower than a first threshold voltage, the second threshold voltage is higher than the first threshold voltage, and the first threshold voltage is a read-out threshold voltage of the main memory in normal operation.

2. The memory device according to claim 1, wherein the plurality of memory cells of the main memory and the monitor memory is electrically connected to a single wordline.

3. The memory device according to claim 1, wherein,
a situation in which a result of reading out the plurality of memory cells of the monitor memory at the second threshold voltage does not satisfy the predetermined first criterion occurs in a situation in which an error occurs in at least one of the plurality of memory cells of the monitor memory, as a result of reading out the plurality of memory cells of the monitor memory at the second threshold voltage, and
the plurality of memory cells of the main memory is read out at the third threshold voltage if a first criterion is not satisfied, and if no error occurs in all of the plurality of memory cells of the monitor memory as a result of reading out the plurality of memory cells of the monitor memory at a fourth threshold voltage, wherein the fourth threshold voltage is lower than the second threshold voltage.

4. The memory device according to claim 1, wherein before reading out the plurality of memory cells of the monitor memory at the second threshold voltage, the plurality of memory cells of the main memory is read out at the first threshold voltage.

5. The memory device according to claim 1, wherein based on a result of reading out the plurality of memory cells of the main memory at the third threshold voltage, the plurality of memory cells of the main memory is refreshed.

6. The memory device according to claim 1, wherein based on a result of reading out the plurality of memory cells of the monitor memory at a fourth threshold voltage that is lower than the second threshold voltage, the plurality of memory cells of the monitor memory is refreshed.

7. The memory device according to claim 1, wherein if a result of reading out the plurality of memory cells of the monitor memory at a fourth threshold voltage that is lower than the second threshold voltage does not satisfy a predetermined second criterion, a flag is set to indicate that a data holding characteristic of the plurality of memory cells of the main memory is abnormal.

8. The memory device according to claim 6, wherein the fourth threshold voltage is higher than or equal to the first threshold voltage.

9. The memory device according to claim 1, wherein if a result of reading out the plurality of memory cells of the monitor memory at the second threshold voltage satisfies the predetermined first criterion, the main memory and the monitor memory are not refreshed.

10. The memory device according to claim 1, wherein,
immediately after writing data on the plurality of memory cells of the main memory, the plurality of memory cells of the main memory has a first threshold voltage distribution and a second threshold voltage distribution which indicate different data values from each other, and
the first threshold voltage that is higher than the third threshold voltage is higher than or equal to a middle threshold voltage between an average value of the first threshold voltage distribution and an average value of the second threshold voltage distribution, and is a voltage less than or equal to a smallest threshold voltage in the first threshold voltage distribution.

11. The memory device according to claim 1, comprising:
a first, a second, and a third wordlines which are adjacently provided; and
a plurality of data lines to intersect each of the first, second and third wordlines, wherein,
the monitor memory includes:
the plurality of memory cells electrically connected to a first wordline respectively;
a plurality of first additional memory cells electrically connected to a second wordline respectively, wherein the second wordline is adjacent to the first wordline and is different from the first wordline; and
a plurality of second additional memory cells electrically connected to a third wordline respectively, wherein the third wordline is adjacent to the second wordline and is different from the first wordline and second wordline,
the plurality of memory cells includes a repeat region in which data are written in a first pattern having different data values,
the plurality of first additional memory cells includes a repeat region in which data are written in a second pattern different from the first pattern, and
the plurality of second additional memory cells includes a repeat region in which data are written in the first pattern.

12. A sensor device comprising:
a pressure sensing unit;
a trimming circuit to adjust current applied to the pressure sensing unit; and
the memory device according to claim 1 that stores trimming data to be supplied to the trimming circuit.
